(19) United States
(12) Patent Application Publication
(10) Pub. No.: US 2016/0274167 A1
(43) Pub. Date: Sep. 22, 2016

(54) BUSS CURRENT-BASED SHORT CIRCUIT FAULT DIAGNOSING METHOD FOR POWER CONVERTER OF SWITCHED RELUCTANCE MOTOR

(71) Applicant: China University of Mining and Technology, Xuzhou, JS (CN)

(72) Inventors: Hao Chen, Xuzhou (CN); Xing Wang, Xuzhou (CN); Shengquan Wang, Xuzhou (CN)

(21) Appl. No.: 15/029,545

(22) PCT Filed: Apr. 14, 2014
(86) PCT No.: PCT/CN2014/075264

§ 371 Date: Apr. 14, 2016

(30) Foreign Application Priority Data
Nov. 19, 2013 (CN) 201310586875.X

(51) Int. Cl. G01R 31/02; H02P 25/092; H02P 29/024; G01R 31/42

(52) U.S. Cl. CPC G01R 31/025; G01R 31/42; H02P 25/092; H02P 29/024

(57) ABSTRACT

A bus current-based short circuit fault diagnosing method for the power converter of a switched reluctance motor, which, by detecting the transient value of bus current in the power converter of a switched reluctance motor, calculates the mean value Δ of maximum wavelet transform coefficient corresponding to bus current under different scale parameters and takes the mean value as a fault characteristic quantity, and utilizes a curve of mean value Δ of maximum wavelet transform coefficient corresponding to bus current in the power converter of the switched reluctance motor under different scale parameters in the entire range of rotation speed to diagnose whether there is a short circuit fault in the position main switches of the power converter of the switched reluctance motor. The method is applicable to the diagnosis of short circuit faults in position main switches of the power converter of a switched reluctance motor in any topological structure with any number of phases, can diagnose short circuit faults accurately, and has a great value in engineering application.

### FIELD OF THE INVENTION

The present invention relates to a bus current-based position main switch short circuit fault diagnosing method for the power converter of a switched reluctance motor, in particular to a bus current-based position main switch short circuit fault diagnosing method for the power converter of a switched reluctance motor in any topological structure with any number of phases.

### BACKGROUND ART

Switched reluctance motor systems employ a power supply approach of non-sinusoidal current and non-sinusoidal voltage, and operate on the basis of a minimum reluctance principle. However, the conventional fault diagnosing methods for power converters of motors can't be directly applied to the power converter of a switched reluctance motor. At present, most fault diagnosing methods for the power converter of a switched reluctance motor are designed for detecting short circuit faults in the main switches of dual-switch power converters. Common-switch power converters are also a type of power converters commonly used in switched reluctance motor systems, and they use less power switches and have lower hardware cost than dual-switch power converters. Therefore, common-switch power converters have advantages over dual-switch power converters in applications. Hence, a fault diagnosing method that is applicable to both dual-switch power converters and common-switch power converters should be developed.

### SUMMARY OF THE INVENTION

In view of the drawbacks in the prior art, the present invention provides a bus current-based diagnosing method for diagnosing short circuit faults in the position main switch of the power converter of a switched reluctance motor, which, by detecting the transient value of bus current in the power converter of a switched reluctance motor, calculates the mean value of maximum wavelet transform coefficient corresponding to bus current under different scale parameters and takes the mean value as a fault characteristic quantity, and thereby diagnoses whether there is a short circuit fault in the position main switch of the power converter of the switched reluctance motor.

The bus current-based position main switch short circuit fault diagnosing method for the power converter of a switched reluctance motor according to the present invention comprises:

detecting the transient value of bus current f(t) in the power converter of a switched reluctance motor; and, according to the following formulas:

$$\begin{matrix}{WT}_{f} ( a , b ) = \frac{1}{2 \sqrt{a}} {\int }_{R} \tilde{f} ( t ) {\tilde{ψ}}^{*} ( \frac{t - b}{a} ) d t & ( 1 ) \\ = \frac{1}{2 \sqrt{a}} {\int }_{R} {A}_{f} ( t ) {A}_{ψ}^{*} ( \frac{t - b}{a} ) \cdot {e}^{j ( {ϕ}_{f} ( t ) \cdot {ϕ}_{ψ} ( \frac{t - b}{a} ) )} d t & ( 2 ) \\ = \frac{1}{2 \sqrt{a}} {\int }_{R} {A}_{a , b} ( t ) {e}^{j {ϕ}_{a , b} ( t )} d t & ( 3 )\end{matrix}$$

calculating the wavelet transform coefficient WT_{f}(a,b) corresponding to the bus current f(t), where, R indicates that the integral interval is a set of real numbers, * represents complex conjugate, t is the time variable corresponding to bus current f(t), a is the scale parameter of wavelet transform, and b is the translation parameter of wavelet transform; in formula (1), \tilde{f}(t) is the analytic signal expression corresponding to bus current f(t), wherein \tilde{f}(t)=f(t)+jf_{H}(t), j is complex symbol, f_{H}(t) is Hilbert transform of bus current f(t), and

$${f}_{H} ( t ) = \frac{1}{π} {\int }_{∞}^{∞} f ( τ ) \frac{1}{t - τ} d τ ,$$

\tilde{ψ}(t) is the analytic form of complex wavelet ω(t), and

$$\tilde{ψ} ( t ) = {A}_{ψ} ( t ) {e}^{j {ϕ}_{ψ} ( t )} = {( 4 π )}^{\frac{1}{2}} \cdot {e}^{\frac{{t}^{2}}{4}} \cdot {e}^{4 π \cdot rj} , and {A}_{ψ} ( t ) = {( 4 π )}^{\frac{1}{2}} \cdot {e}^{\frac{{t}^{2}}{4}}$$

is the amplitude of complex wavelet ψ(t), and φ_{ψ}(t)=6π·t is the phase of complex wavelet ψ(t); in formula (2), j is complex symbol, A_{f}(t) is the amplitude of bus current f(t), φ_{f}(t) is the phase of bus current f(t), and Aⱼ(t)e^{jφ}^{_{f}}^{(t)}=\tilde{f}(t), and

$${A}_{ψ}^{*} ( \frac{t - b}{a} ) {e}^{- j {ϕ}_{ψ} ( \frac{t - b}{a} )} = {\tilde{ψ}}^{*} ( \frac{t - b}{a} ) ;$$

in formula (3), j is complex symbol, and

$${A}_{a , b} ( t ) = {A}_{f} ( t ) {A}_{ψ}^{*} ( \frac{t - b}{a} ) , {φ}_{a , b} ( t ) = {ϕ}_{f} ( t ) - {ϕ}_{ψ} ( \frac{t - b}{a} ) ;$$

taking the mean value Δ of maximum wavelet transform coefficient WT_{f}(a,b) corresponding to bus current f(t) under different scale parameters as a fault characteristic quantity, i.e.,

$$Δ = \frac{1}{b} {\sum }_{b = 1}^{b} {{WT}_{f} ( a , b )}_{max} ,$$

so as to diagnose whether there is a short circuit fault in the main circuit of the power converter of the switched reluctance motor;
if the curve of mean value Δ of maximum wavelet transform coefficient WT_{f}(a,b) corresponding to bus current f(t) under different scale parameters are all higher than 0.09 in the entire range of rotation speed, then it can be judged that there is a short circuit fault in the position main switch of the power converter of the switched reluctance motor.

Beneficial effects: the present invention is applicable to the diagnosis of short circuit faults in the position main switch of the power converter of a switched reluctance motor in any topological structure with any number of phases. By detecting the transient value of bus current in the power converter of a switched reluctance motor, the mean value Δ of maximum wavelet transform coefficient corresponding to bus current under different scale parameters is calculated and taken as a fault characteristic quantity; utilizing a curve of mean value Δ of maximum wavelet transform coefficient corresponding to bus current in the power converter of the switched reluctance motor under different scale parameters in the entire range of rotation speed, whether there is a short circuit fault in the position main switch of the power converter of the switched reluctance motor can be diagnosed, and thereby the object of the present invention is attained. The fault diagnosing method for the power converter of a switched reluctance motor is applicable to the diagnosis of short circuit faults in the position main switches of dual-switch power converters and the diagnosis of short circuit faults in the position main switches of common-switch power converters as well as the diagnosis of short circuit faults in the position main switches in any other topological structure. The diagnosis of short circuit faults in position main switches is accurate, the method thereof is simple, can achieve a good diagnostic result, and is of a great value in engineering application.

### BRIEF DESCRIPTION OF THE DRAWINGS

FIG. 1 is a topological structure diagram of a three-phase common-switch power converter of a switched reluctance motor for which the present invention is applied;

FIG. 2 is a curve diagram of mean value Δ of maximum wavelet transform coefficient corresponding to bus current under different scale parameters of a three-phase common-switch power converter of a switched reluctance motor for which the present invention is applied, in the entire range of rotation speed;

FIG. 3 shows a transient waveform of bus current f(t) in a three-phase common-switch power converter of a switched reluctance motor for which the present invention is applied, when the rotation speed of the switched reluctance motor is 700 rpm and there is no fault;

FIG. 4 shows a transient waveform of bus current f(t) in a three-phase common-switch power converter of a switched reluctance motor for which the present invention is applied, when the rotation speed of the switched reluctance motor is 700 rpm and there is a short circuit fault in the position main switch;

FIG. 5 is a topological structure diagram of a three-phase dual-switch power converter of a switched reluctance motor for which the present invention is applied.

### DETAILED DESCRIPTION OF THE EMBODIMENTS

Hereunder the present invention will be detailed in embodiments with reference to the accompanying drawings:

### Embodiment 1

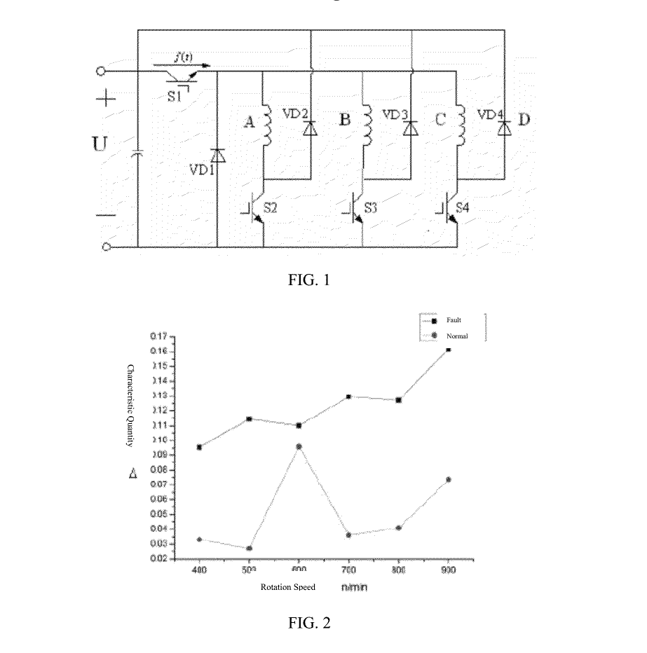

As shown in FIG. 1, in the main circuit of a three-phase common-switch power converter of a switched reluctance motor, each phase has a main switch and a freewheeling diode, phases A, B, and C are connected in parallel to the negative pole “−” of power supply U, and phases A, B, and C are also connected in parallel to the positive pole “+” of the power supply U via the common switch S1 and the common freewheeling diode VD1. One end of the common switch S1 is connected to the positive pole “+” of the power supply, the other end of the common switch S1 is connected to one end of the winding of phase A, one end of the position main switch S2 of phase A is connected to the negative pole “−” of the power supply, the other end of the position main switch S2 of phase A is connected to the other end of the winding of phase A, one end of the freewheeling diode VD2 of phase A is connected to the positive pole “+” of the power supply U, the other end of the freewheeling diode VD2 of phase A is connected to the other end of the winding of phase A, one end of the common freewheeling diode VD1 is connected to the negative pole “−” of the power supply U, and the other end of the common freewheeling diode VD1 is connected to one end of the winding of phase A. The internal connections manner in phase B and phase C are identical to the internal connections manner in phase A; therefore, the description is omitted here. The bus current-based position main switch short circuit fault diagnosing method for the power converter of a switched reluctance motor is as follows: First, the transient value of bus current f(t) in the power converter of a switched reluctance motor is detected; and, according to the following formulas:

$$\begin{matrix}{WT}_{f} ( a , b ) = \frac{1}{2 \sqrt{a}} {\int }_{R} \tilde{f} ( t ) {\tilde{ψ}}^{*} ( \frac{t - b}{a} ) d t & ( 1 ) \\ = \frac{1}{2 \sqrt{a}} {\int }_{R} {A}_{f} ( t ) {A}_{ψ}^{*} ( \frac{t - b}{a} ) \cdot {e}^{j ( {ϕ}_{f} ( t ) \cdot {ϕ}_{ψ} ( \frac{t - b}{a} ) )} d t & ( 2 ) \\ = \frac{1}{2 \sqrt{a}} {\int }_{R} {A}_{a , b} ( t ) {e}^{j {ϕ}_{a , b} ( t )} d t & ( 3 )\end{matrix}$$

the wavelet transform coefficient WT_{f}(a,b) corresponding to the bus current f(t) is calculated, where, R indicates that the integral interval is a set of real numbers, * represents complex conjugate, t is the time variable corresponding to bus current f(t), a is the scale parameter of wavelet transform, and b is the translation parameter of wavelet transform; in formula (1), \tilde{f}(t) is the analytic signal expression corresponding to bus current f(t), wherein \tilde{f}(t)=f(t)+jf_{H}(t), j is complex symbol, f_{H}(t) is Hilbert transform of bus current f(t), and

$${f}_{H} ( t ) = \frac{1}{π} {\int }_{∞}^{∞} f ( τ ) \frac{1}{t - τ} d τ ,$$

\tilde{ψ}(t) is the analytic form of complex wavelet ψ(t), wherein

$$\tilde{ψ} ( t ) = {A}_{ψ} ( t ) {e}^{j {ϕ}_{ψ} ( t )} = {( 4 π )}^{\frac{1}{2}} \cdot {e}^{\frac{{t}^{2}}{4}} \cdot {e}^{4 π \cdot rj} , and {A}_{ψ} ( t ) = {( 4 π )}^{\frac{1}{2}} \cdot {e}^{\frac{{t}^{2}}{4}}$$

is the amplitude of complex wavelet ψ(t), and φ_{ψ}(t)=6π·t is the phase of complex wavelet ψ(t); in formula (2), j is complex symbol, A_{f}(t) is the amplitude of bus current f(t), φ_{f}(t) is the phase of bus current f(t), and A_{f}(t)e^{jφ}^{_{f}}^{(t)}=\tilde{f}(t), and

$${A}_{a , b} ( t ) = {A}_{f} ( t ) {A}_{ψ}^{*} ( \frac{t - b}{a} ) = {\tilde{ψ}}^{*} ( \frac{t - b}{a} ) ;$$

in formula (3), j is complex symbol, and

$${A}_{a , b} ( t ) = {A}_{f} ( t ) {A}_{ψ}^{*} ( \frac{t - b}{a} ) , {φ}_{a , b} ( t ) = {ϕ}_{f} ( t ) - {ϕ}_{ψ} ( \frac{t - b}{a} ) .$$

The mean value Δ of maximum wavelet transform coefficient WT_{f}(a,b) corresponding to bus current f(t) under different scale parameters is taken as a fault characteristic quantity, i.e.,

$$Δ = \frac{1}{b} {\sum }_{b = 1}^{b} {{WT}_{f} ( a , b )}_{max} ,$$

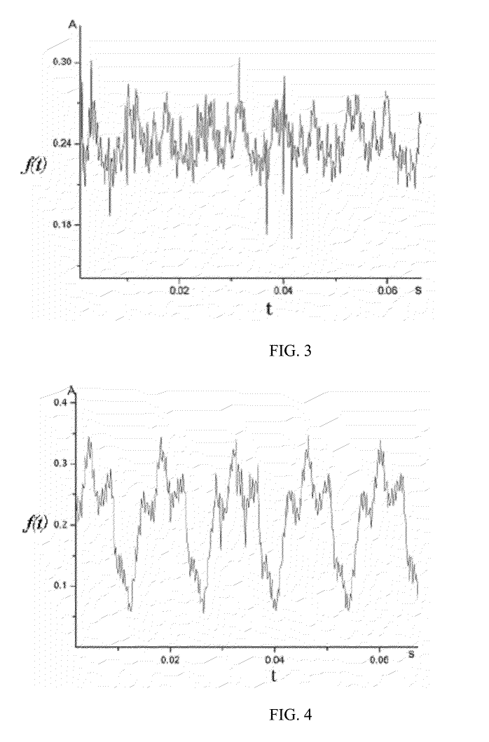

and whether there is a short circuit fault in the main circuit of the power converter of the switched reluctance motor can be diagnosed. As shown in FIG. 2, if the curve of mean value Δ of maximum wavelet transform coefficient WT_{f}(a,b) corresponding to bus current f(t) under different scale parameters are all higher than 0.09 in the entire range of rotation speed, then there is a short circuit fault in the position main switch of the three-phase common-switch power converter of the switched reluctance motor.

For example, if the rotation speed of the switched reluctance motor is 700 rpm, the transient waveform of bus current f(t) without fault is shown in FIG. 3, and the fault characteristic quantity Δ=0.0361, then there is no fault. If the rotation speed of the switched reluctance motor is 700 rpm, the transient waveform of bus current f(t) with a short circuit fault in the position main switch is shown in FIG. 4, and the fault characteristic quantity Δ=0.1296, i.e., greater than 0.09, then there is a short circuit fault in the position main switch.

### Embodiment 2

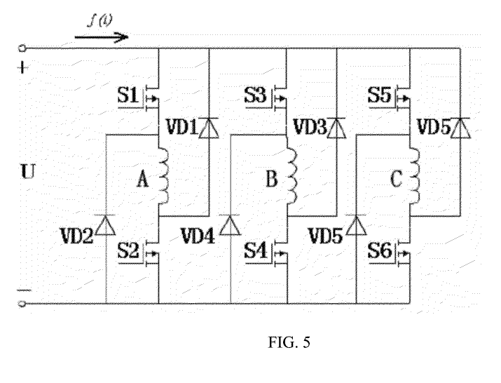

as shown in FIG. 5, in the main circuit of a three-phase dual-switch power converter of a switched reluctance motor, each phase has two main switches and two freewheeling diodes, and phases A, B, and C are connected in parallel to the positive pole “+” and negative pole “−” of the power supply U; wherein, one end of the upper main switch S1 of phase A is connected to the positive pole “+” of the power supply U, the other end of the upper main switch S1 is connected to one end of the winding of phase A, one end of the lower main switch S2 is connected to the negative pole “−” of the power supply U, the other end of the lower main switch S2 is connected to the other end of the winding of phase A, one end of the upper freewheeling diode VD1 is connected to the positive pole “+” of the power supply U, the other end of the upper freewheeling diode VD1 is connected to the other end of the winding of phase A, one end of the lower freewheeling diode VD2 is connected to the negative pole “−” of the power supply U, and the other end of the lower freewheeling diode VD2 is connected to one end of the winding of phase A. The internal connections in phase B and phase C are identical to the internal connections in phase A; therefore, the description is omitted here. The bus current-based position main switch short circuit fault diagnosing method for the power converter of a switched reluctance motor is as follows:

First, the transient value of bus current f(t) in the three-phase dual-switch power converter of a switched reluctance motor is detected; then, according to the following formulas:

$$\begin{matrix}{WT}_{f} ( a , b ) = \frac{1}{2 \sqrt{a}} {\int }_{R} \tilde{f} ( t ) {\tilde{ψ}}^{*} ( \frac{t - b}{a} ) d t & ( 4 ) \\ = \frac{1}{2 \sqrt{a}} {\int }_{R} {A}_{f} ( t ) {A}_{ψ}^{*} ( \frac{t - b}{a} ) \cdot {e}^{j ( {ϕ}_{f} ( t ) - {ϕ}_{ψ} ( \frac{t - b}{a} ) )} d t & ( 5 ) \\ = \frac{1}{2 \sqrt{a}} {\int }_{R} {A}_{a , b} ( t ) {e}^{j {φ}_{a , b} ( t )} d t & ( 6 )\end{matrix}$$

the wavelet transform coefficient WT_{f}(a,b) corresponding to the bus current f(t) is calculated, where, R indicates that the integral interval is a set of real numbers, * represents complex conjugate, t is the time variable corresponding to bus current f(t), a is the scale parameter of wavelet transform, and b is the translation parameter of wavelet transform; in formula (4), \tilde{f}(t) is the analytic signal expression corresponding to bus current f(t), wherein \tilde{f}(t)=f(t)+jf_{H}(t), j is complex symbol, f_{H}(t) is Hilbert transform of bus current f(t), wherein

$${f}_{H} ( t ) = \frac{1}{π} {\int }_{- ∞}^{∞} f ( τ ) \frac{1}{t - τ} d τ ,$$

\tilde{ψ}(t) is the analytic form of complex wavelet ψ(t), wherein

$$\tilde{ψ} ( t ) = {A}_{ψ} ( t ) {e}^{j {ϕ}_{ψ} ( t )} = {( 4 π )}^{- \frac{1}{2}} \cdot {e}^{- \frac{{t}^{2}}{4}} \cdot {e}^{6 π \cdot {t}_{j}} , and$$

$${A}_{ψ} ( t ) = {( 4 π )}^{- \frac{1}{2}} \cdot {e}^{- \frac{{t}^{2}}{4}}$$

is the amplitude of complex wavelet ω(t), and φ_{ψ}=6π·t is the phase of complex wavelet ψ(t); in formula (5), j is complex symbol, A_{f}(t) is the amplitude of bus current f(t), φ^{f}(t) is the phase of bus current f(t), and A_{f}(t)e^{jφ}^{_{f}}^{(t)}=\tilde{f}(t),

$${A}_{ψ}^{*} ( \frac{t - b}{a} ) {e}^{- j {ϕ}_{ψ} ( \frac{t - b}{a} )} = {\tilde{ψ}}^{*} ( \frac{t - b}{a} ) ;$$

in formula (6), j is complex symbol, and

$${A}_{a , b} ( t ) = {A}_{f} ( t ) {A}_{ψ}^{*} ( \frac{t - b}{a} ) , {φ}_{a , b} ( t ) = {ϕ}_{f} ( t ) - {ϕ}_{ψ} ( \frac{t - b}{a} ) .$$

The mean value Δ of maximum wavelet transform coefficient WT_{f}(a,b) corresponding to bus current f(t) under different scale parameters is taken as a fault characteristic quantity, i.e.,

$$Δ = \frac{1}{b} {\sum }_{b = 1}^{b} {{WT}_{f} ( a , b )}_{max} ,$$

and whether there is a short circuit fault in the main circuit of the power converter of the switched reluctance motor can be diagnosed;

As shown in FIG. 2, if the curve of mean value Δ of maximum wavelet transform coefficient WT_{f}(a,b) corresponding to bus current f(t) under different scale parameters are all higher than 0.09 in the entire range of rotation speed, then there is a short circuit fault in the position main switch of the three-phase dual-switch power converter of the switched reluctance motor.

1. A bus current-based short circuit fault diagnosing method for the power converter of a switched reluctance motor, comprising:
detecting the transient value of bus current f(t) in the power converter of a switched reluctance motor; and
calculating a wavelet transform coefficient WT_{f}(a,b) corresponding to the bus current f(t) according to the following formulas:
$$\begin{matrix}{WT}_{f} ( a , b ) = \frac{1}{2 \sqrt{a}} {\int }_{R} \tilde{f} ( t ) {\tilde{ψ}}^{*} ( \frac{t - b}{a} ) d t & ( 1 ) \\ = \frac{1}{2 \sqrt{a}} {\int }_{R} {A}_{f} ( t ) {A}_{ψ}^{*} ( \frac{t - b}{a} ) \cdot {e}^{j ( {ϕ}_{f} ( t ) - {ϕ}_{ψ} ( \frac{t - b}{a} ) )} d t & ( 2 ) \\ = \frac{1}{2 \sqrt{a}} {\int }_{R} {A}_{a , b} ( t ) {e}^{j {φ}_{a , b} ( t )} d t & ( 3 )\end{matrix}$$
where, R indicates that the integral interval is a set of real numbers, * represents complex conjugate, t is the time variable corresponding to bus current f(t), a is the scale parameter of wavelet transform, and b is the translation parameter of wavelet transform; in formula (1), \tilde{f}(t) is the analytic signal expression corresponding to bus current f(t), and \tilde{f}(t)=f(t)+jf_{H}(t), j is complex symbol, f_{H}(t) is Hilbert transform of bus current f(t), and
$${f}_{H} ( t ) = \frac{1}{π} {\int }_{- ∞}^{∞} f ( τ ) \frac{1}{t - τ} d τ ,$$
\tilde{ψ}(t) is the analytic form of complex wavelet ψ(t), and
$$\tilde{ψ} ( t ) = {A}_{ψ} ( t ) {e}^{j {ϕ}_{ψ} ( t )} = {( 4 π )}^{- \frac{1}{2}} \cdot {e}^{- \frac{{t}^{2}}{4}} \cdot {e}^{6 π \cdot {t}_{j}} , {A}_{ψ} ( t ) = {( 4 π )}^{- \frac{1}{2}} \cdot {e}^{- \frac{{t}^{2}}{4}}$$
is the amplitude of complex wavelet ψ(t), and φ_{ψ}(t)=6π·t is the phase of complex wavelet ψ(t); in formula (2), j is complex symbol, A_{f}(t) is the amplitude of bus current f(t), φ_{f}(t) is the phase of bus current f(t), and A_{f}(t)e^{jφ}^{_{f}}^{(t)}=\tilde{f}(t),
$${A}_{ψ}^{*} ( \frac{t - b}{a} ) {e}^{- j {ϕ}_{ψ} ( \frac{t - b}{a} )} = {\tilde{ψ}}^{*} ( \frac{t - b}{a} ) ;$$
in formula (3), j is complex symbol, and
$${A}_{a , b} ( t ) = {A}_{f} ( t ) {A}_{ψ}^{*} ( \frac{t - b}{a} ) , {φ}_{a , b} ( t ) = {ϕ}_{f} ( t ) - {ϕ}_{ψ} ( \frac{t - b}{a} ) ;$$
taking the mean value Δ of maximum wavelet transform coefficient WT_{f}(a,b) corresponding to bus current f(t) under different scale parameters as a fault characteristic quantity, i.e.,
$$Δ = \frac{1}{b} {\sum }_{b = 1}^{b} {{WT}_{f} ( a , b )}_{max} ,$$
and diagnosing whether there is a short circuit fault in the main circuit of the power converter of the switched reluctance motor;
wherein if the curve of mean value Δ of maximum wavelet transform coefficient WT_{f}(a,b) corresponding to bus current f(t) under different scale parameters are all higher than 0.09 in the entire range of rotation speed, then it can be judged that there is a short circuit fault in the position main switch of the power converter of the switched reluctance motor.
